(19) United States
(12) Patent Application Publication
(10) Pub. No.: US 2023/0028527 A1
(43) Pub. Date: Jan. 26, 2023

(54) VIA STRUCTURE, METHOD FOR PREPARING SAME AND METHOD FOR REGULATING IMPEDANCE OF VIA STRUCTURE

(71) Applicant: CHANGXIN MEMORY TECHNOLOGIES, INC., Hefei City (CN)

(72) Inventor: Yade FANG, Hefei (CN)

(21) Appl. No.: 17/486,459

(22) Filed: Sep. 27, 2021

Related U.S. Application Data
(63) Continuation of application No. PCT/CN2021/110787, filed on Aug. 5, 2021.

(30) Foreign Application Priority Data
Jul. 20, 2021 (CN) 202110820250.X

(51) Int. Cl. H05K 1/11; H05K 1/02; H05K 3/42

(52) U.S. Cl. CPC H05K 1/116; H05K 1/0251; H05K 3/429; H05K 2201/0959

(57) ABSTRACT

Embodiments of the disclosure provide a via structure, a method for preparing the same and a method for regulating impedance of a via structure. The via structure includes a first via, a second via and a first connecting through hole; and a first metal layer a the second metal layer. The first connecting through hole is located between the first via and the second via, and covers part of the first via and part of the second via. The first metal layer and the second metal layer are respectively located in the first via and the second via. The first metal layer and the second metal layer respectively cover a sidewall of the first via and a sidewall of the second via. The first metal layer is separated from the second metal layer through the first connecting through hole.

### CROSS-REFERENCE TO RELATED APPLICATIONS

The present application is a U.S. continuation application of International Application No. PCT/CN2021/110787, filed on Aug. 5, 2021, which claims priority to Chinese Patent Application No. 202110820250.X, filed on Jul. 20, 2021. International Application No. PCT/CN2021/110787 and Chinese Patent Application No. 202110820250.X are incorporated herein by reference in their entireties.

### TECHNICAL FIELD

The disclosure relates, but is not limited, to a via structure, a method for preparing the same and a method for regulating impedance of a via structure.

### BACKGROUND

A via is an electrical interconnection which usually pass through a multi-layer printed circuit board (PCB) and provides an electrical connection among through layers of PCB. Usually, a via allows that a path line in one layer of PCB is connected to that in another layer of the PCB. Successively, the path line is also connected to a circuit, an electrical device, a contact pad and a connector, etc. At present, how to effectively control the impedance of the via has become an important research direction.

### SUMMARY

For that reason, embodiments of the present disclosure provide a via structure, a method for preparing the same and a method for regulating impedance of a via structure.

According to a first aspect of the embodiments of the present disclosure, a via structure is provided. The via structure includes a first via, a second via, a first connecting through hole, a first metal layer and a second metal layer.

The first connecting through hole is located between the first via and the second via. The first connecting through hole covers part of the first via and part of the second via.

The first metal layer and the second metal layer are respectively located in the first via and the second via. The first metal layer and the second metal layer respectively cover a sidewall of the first via and a sidewall of the second via. The first metal layer is separated from the second metal layer by the first connecting through hole.

According to a second aspect of the embodiments of the present disclosure, a via structure is provided. The via structure includes a first via, a first connecting through hole, a second connecting through hole, a first metal layer and a second metal layer.

The first connecting through hole and the second connecting through hole are respectively located at two sides of the first via, and cover part of first via.

The first metal layer and the second metal layer are located in the first via. The first metal layer and the second metal layer cover a sidewall of the first via and are separated from each other by the first connecting through hole and the second connecting through hole.

According to a third aspect of the embodiments of the present disclosure, a method for preparing a via structure is provided. The method includes the following operations.

A first via and a second via are formed.

A first pre-metal layer and a second pre-metal layer are formed. The first pre-metal layer and the second pre-metal layer respectively cover a sidewall of the first via and a sidewall of the second via.

A first connecting through hole is formed. The first connecting through hole is located between the first via and the second via and covers part of the first via and part of the second via, so as to remove part of the first pre-metal layer and part of the second pre-metal layer that are covered by the first connecting through hole. A first metal layer and a second metal layer are respectively formed. The first metal layer is separated from the second metal layer through the first connecting through hole.

According to a fourth aspect of the embodiments of the present disclosure, a method for preparing a via structure is provided. The method includes the following operations.

A first via is formed.

A first pre-metal layer is formed in the first via. The first pre-metal layer covers a sidewall of the first via.

A first connecting through hole and a second connecting through hole are formed. The first connecting through hole and the second connecting through hole are respectively located at two sides of the first via. The first connecting through hole and the second connecting through hole cover part of first via, so as to remove part of the first pre-metal layer covered by the first connecting through hole and part of first pre-metal layer covered by the second connecting through hole. The first pre-metal layer is disconnected by the first connecting through hole and the second connecting through hole, so that a first metal layer and a second metal layer are formed.

According to a fifth aspect of the embodiments of the present disclosure, a method for regulating impedance of a via structure there is provided. The method includes the following operations.

A via structure is provided. The via structure includes a first via, a second via, a first connecting through hole, a first metal layer, a second metal layer and a dielectric material. The first connecting through hole is located between the first via and the second via. The first connecting through hole covers part of first via and part of second via. The first metal layer is located in the first via. The second metal layer is located in the second via. The first metal layer is separated from the second metal layer by the first connecting through hole. The first metal layer and the second metal layer respectively cover a sidewall of the first via and a sidewall of the second via. The dielectric material fills the first via, the second via and the first connecting through hole.

The impedance of the via structure is regulated based on structure parameters of the via structure. The structure parameters include a distance between the first via and a second via, a thickness of the first metal layer and the second metal layer, a radius of the first via and the second via and a dielectric constant of the dielectric material.

### BRIEF DESCRIPTION OF THE DRAWINGS

FIG. 1 is a structure diagram illustrating a via structure according to embodiments of the disclosure.

FIG. 2A to FIG. 2B are structure diagrams illustrating a first via and a second via according to different embodiments of the disclosure.

FIG. 3A is a structure diagram illustrating a via structure according to another embodiment of the disclosure.

FIG. 3B is a structure diagram illustrating a via structure according to another embodiment of the disclosure.

FIG. 4 is a structure diagram illustrating a via structure according to yet another embodiment of the disclosure.

FIG. 5 is a flowchart illustrating a method for preparing a via structure according to embodiments of the disclosure.

FIG. 6A to FIG. 6D are structure diagrams illustrating a via structure according to embodiments of the disclosure during the preparation.

FIG. 7 is a flowchart illustrating a method for preparing a via structure according to embodiments of the disclosure.

FIG. 8A to FIG. 8D are structure diagrams illustrating a via structure according to embodiments of the disclosure during the preparation.

FIG. 9 is a flowchart illustrating a method for regulating impedance of a via structure according to embodiments of the disclosure.

### DETAILED DESCRIPTION

The following clearly describes the exemplary implementation modes of the disclosure with reference to the drawings. Although the drawings show exemplary implementation modes of the disclosure, it should be understood that the disclosure can be implemented in various forms and shall not be limited by implementation modes described herein. On the contrary, providing these embodiments is to understand the disclosure thoroughly, and the scope of the disclosure can be completely conveyed to technicians in the art.

A number of specific details are given below to provide a more thorough understanding of the disclosure. However, it is apparent to those skilled in the art that the disclosure can be implemented without one or more of these details. In other examples, to avoid confusion with the disclosure, some technical features known in the art are not described; namely, all the features of the actual embodiments are not described here, nor are known functions and structures described in detail.

In the drawings, dimensions of layers, regions, components and their relative dimensions may be exaggerated for clarity. The same drawing marks throughout represent the same components.

It is to be understood that description that an element or layer is “on”, “adjacent to”, “connected to”, or “coupled to” another element or layer may refer to that the element or layer is directly on, adjacent to, connected to or coupled to the other element or layer, or there may be an intermediate element or layer. On the contrary, description that an element is “directly on”, “directly adjacent to”, “directly connected to” or “directly coupled to” another element or layer refers to that there is no intermediate element or layer. It is to be understood that, although various elements, components, regions, layers and/or parts may be described with terms first, second, third, etc., these elements, components, regions, layers and/or parts should not be limited to these terms. These terms are used only to distinguish one element, component, region, layer or part from another element, component, region, layer or part. Therefore, a first element, component, region, layer or part discussed below may be represented as a second element, component, region, layer or part without departing from the teaching of the disclosure. However, when discussing a second element, component, region, layer or part, it does not necessarily imply the existence of a first element, component, region, layer or part of the disclosure.

Spatially relational terms such as “below”, “under”, “lower”, “beneath”, “above”, and “upper” may be used herein for describing a relationship between one element or feature and another element or feature illustrated in the figures. It is to be understood that, in addition to the orientation shown in the figures, the spatially relational terms further include different orientations of devices in use and operation. For example, if the devices in the figures are turned over, elements or features described as being “under” or “beneath” or “below” other elements or features will be oriented to be “on” the other elements or features. Therefore, the exemplary terms “under” and “below” may include both upper and lower orientations. Moreover, the device may include otherwise orientation (such as rotation by 90 degrees or in other orientations) and the spatial descriptors used herein may be interpreted accordingly.

The terms used herein are for the purpose of describing specific embodiments only and not intended to limit the disclosure. As used herein, singular forms “a/an”, “the”, and “said” are also intended to include the plural forms, unless otherwise specified in the context. It is also to be understood that, when terms “comprising” and/or “including” are used in this specification, the presence of the features, integers, steps, operations, elements, and/or components is determined, but the presence or addition of one or more other features, integers, steps, operations, elements, components, and/or groups is also possible. As used herein, term “and/or” includes any and all combinations of the related listed items.

In order to thoroughly understand the disclosure, detailed steps and detailed structure will be presented in the following description to explain the technical solution of the disclosure. Optional embodiments of the disclosure are described in details below, however in addition to these detailed descriptions, and the disclosure may have other implementation modes.

In the present PCB design, a differential signal or a single-ended signal needs to be separately drilled during layer exchanging, and a hole pitch is relatively great. Thus, the differential signal cannot form tight coupling, and a return path of the single-ended signal is blocked by a dielectric layer, which forms a cross-split transmission.

Moreover, the impedance of the via cannot be effectively controlled in a related art, such that the impedance cannot be matched when the signal is transmitted through the via, and a reflection is resulted.

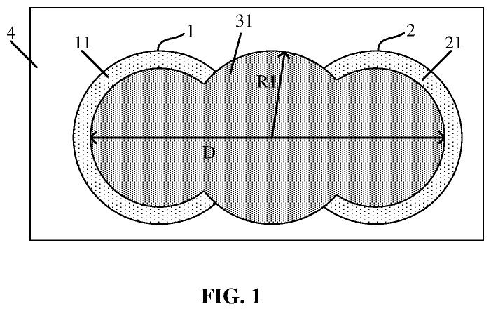

Based on this, the embodiments of the disclosure provide a via structure. FIG. 1 is a structure diagram illustrating a via structure according to embodiments of the disclosure.

Referring to FIG. 1, the via structure includes a first via 1, a second via 2, a first connecting through hole 31, a first metal layer 11 and a second metal layer 21. The first connecting through hole 31 is located between the first via 1 and the second via 2, and covers part of first via 1 and part of second via 2. The first metal layer 11 and the second metal layer 21 are respectively located in the first via 1 and the second via 2. The first metal layer 11 is separated from the second metal layer 21 by the first connecting through hole 31. The first metal layer 11 and the second metal layer 21 respectively cover a sidewall of the first via 1 and a sidewall of the second via 2.

In the embodiments of the disclosure, the first via is tightly joined with the second via through the connecting through hole, so as to solve a problem that a signal is not protected by a reference layer when passing through the via, improve a problem of an incomplete return path in the via structure, form a protection to the signal, avoid cross-split of the return path, and reduce a vertical crosstalk among signals. Meanwhile, the impedance of the via structure can be controlled and adjusted, such that the impedance is continuous and the signal quality is improved.

In an embodiment, the via structure further includes a substrate 4. The first via 1, the second via 2 and the first connecting through hole 31 are arranged on the substrate 4. In an actual operation, the substrate 4 includes, but is not limited to a PCB.

In an embodiment, a dielectric material is filled in the first via 1, the second via 2 and the first connecting through hole 31. After filling the dielectric material, the first via is fused with the second via, such that a distance between a signal of the first via and a signal of the second via can be controlled to a certain extent by regulating the radius of the first via and the second via, the thickness of the first metal layer and the second metal layer and the distance between the first via and the second via. The first metal layer, the dielectric material and the second metal layer may form a capacitor similar to a plane-parallel capacitor, and the impedance design and control are performed according to the distance between the two signals and a dielectric constant of the dielectric material.

In an embodiment, the radius of the first via 1 is equal to that of the second via 2. The thickness of the first metal layer 11 is equal to that of the second metal layer 21. It can be understood that when the radius of the first via is set to be equal to that of the second via, and the thickness of the first metal layer is set to be equal to that of the second metal layer, it allows that the first via and the second via, as well as the first metal layer and the second metal layer can be prepared in a same process step by using a same set of device. As a result, the process operation can be simplified, and the process cost is reduced.

It is to be noted that the radius of the first via may be unequal to that of the second via, and the thickness of the first metal layer may also be unequal to that of the second metal layer, in order to apply to different applications.

In an embodiment, the first via 1 and the second via 2 are partially overlapped.

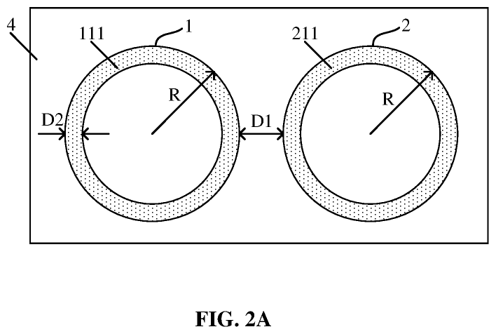

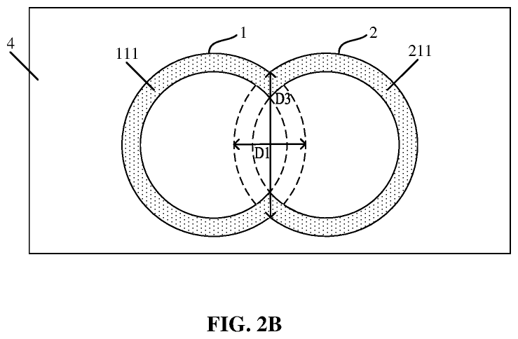

FIG. 2A to FIG. 2B are structure diagrams illustrating a first via and a second via according to different embodiments of the disclosure. As shown in FIG. 2A, a certain distance is spaced between the first via 1 and the second via 2. Specifically, the distance from the first via 1 to the second via 2 is a first distance D1 as shown in FIG. 2A. In the embodiment as shown in FIG. 2A, the first distance D1 is a shortest distance from the first via to the second via along a direction of a connecting line between a center of the first via and a center of the second via. In this embodiment, the first distance D1 is a positive number.

As shown in FIG. 2B, the first via 1 and the second via 2 are partially overlapped. Specifically, the distance from the first via 1 to the second via 2 is a first distance D1 as shown in FIG. 2B. In the embodiment as shown in FIG. 2B, the first distance D1 is a longest distance from the first via to the second via in an overlapping part of the first via and the second via along a direction of a connecting line between a center of the first via and a center of the second via. In this embodiment, the first distance D1 is a negative value of the longest distance.

In some other embodiments, the first via may be tangent to the second via (not shown in the drawings). In this embodiment, the distance from the first via to the second via is 0.

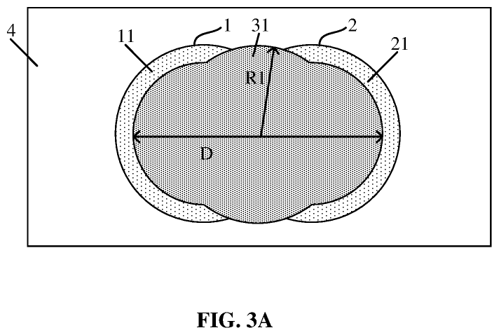

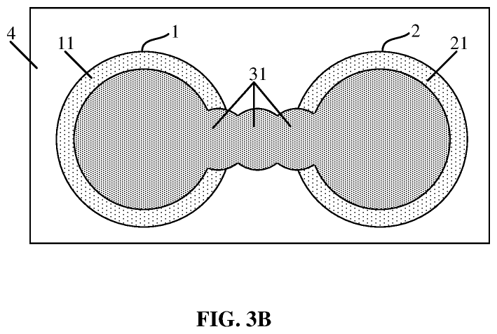

FIG. 3A is a structure diagram illustrating a via structure according to another embodiment of the disclosure, and FIG. 3A is a via structure formed after preparing the first connecting through hole based on the structures of the first via and the second via as shown in FIG. 2B.

In the embodiment as shown in FIG. 2B and FIG. 3A, D3<2*R1. R1 represents the radius of the first connecting through hole 31, and D3 represents a longest distance of an overlapping part of the first via 1 and the second via 2 along a direction perpendicular to a connecting line between a center of the first via 1 and a center of the second via 2. By doing so, a first pre-metal layer 111 of the first via 1 and a second pre-metal layer 211 of the second via 2 are disconnected through the first connecting through hole 31, and the first metal layer and the second metal layer that are separated through the first connecting through hole are formed, to prevent a short circuit resulted by the connection of the first metal layer with the second metal layer.

In an embodiment, a center of the first connecting through hole 31 is a midpoint of the connecting line between the center of the first via 1 and the center of the second via 2. The first connecting through hole 31 covers the first via 1 and the second via 2 with same area, such that the area of the first metal layer 11 is equal to that of the second metal layer 21. It can be understood that and in a case that the radius of the first via 1 is equal to that of the second via 2, and the thickness of the first metal layer 11 is equal to that of the second metal layer 21, the formed first metal layer and the second metal layer have the same area when area of the first via covered by the first connecting through hole equals to area of the second via covered by the first connecting through hole, namely, the first pre-metal layer and the second pre-metal layer are removed with same area. Thus, the impedance of the via structure can be well controlled and adjusted; meanwhile, the signal quality is also improved.

FIG. 3B is a structure diagram illustrating a via structure according to another embodiment of the disclosure. As shown in FIG. 3B, the quantity of the first connecting through hole may be multiple, and the adjacent first connecting through holes are mutually overlapped. The multiple first connecting through holes may have the equal or unequal radius.

It is to be noted that person skilled in the art should aware that, in the embodiments of the disclosure, the first connecting through hole setting in a circular shape only intends to illustrate the application of the disclosure, and is not intended to limit the disclosure in any forms. The first connecting through hole may also be any other shapes such as a rectangle, a pentagon and any other polygons.

In an embodiment, the first via 1 is a signal via, and the second via 2 is a reference via.

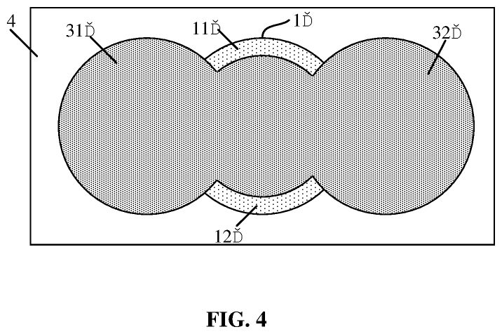

Embodiments of the disclosure further provide a via structure. FIG. 4 is a structure diagram illustrating a via structure according to yet another embodiment of the disclosure.

As shown in FIG. 4, the via structure includes a first via 1′, a first connecting through hole 31′, a second connecting through hole 32′, a first metal layer 11′ and a second metal layer 12′. The first connecting through hole 31′ and the second connecting through hole 32′ are respectively located at the two sides of the first via 1′ and cover a part of the first via 1′. The first metal layer 11′ and the second metal layer 12′ are located in the first via 1′. The first metal layer 11′ and the second metal layer 12′ cover a sidewall of the first via 1′ and are separated from each other through the first connecting through hole 31′ and the second connecting through hole 32′.

In an embodiment, the via structure further includes a substrate 4. The first via 1′, the first connecting through hole 31′ and the second connecting through hole 32′ are arranged on the substrate 4.

In an embodiment, a dielectric material is filled in the first via 1′, the first connecting through hole 31′ and the second connecting through hole 32′. The first metal layer 11′, the dielectric material and the second metal layer 12′ form a capacitor. Specifically, the first metal layer, the dielectric material and the second metal layer may form a capacitor similar to a plane-parallel capacitor. The impedance design and control are performed according to the distance between the first metal layer and the second metal layer and the dielectric constant of the dielectric material.

In an embodiment, a connecting line among the center of the first via 1′, the center of the first connecting through hole 31′ and the center of the second connecting through hole 32′ is a straight line, such that the area of the first metal layer 11′ is equal to that of the second metal layer 12′. Thus, the impedance of the via structure can be well controlled and adjusted. Meanwhile, the signal quality is also improved.

It is to be noted that person skilled in the art should aware that, in the embodiments of the disclosure, the first connecting through hole and the second connecting hole setting in a circular shape only intends to illustrate the application of the disclosure, and are not intended to limit the disclosure in any forms. The first connecting through hole and the second connecting through hole may also be any other shapes, for example, a rectangle, a pentagon and any other polygons.

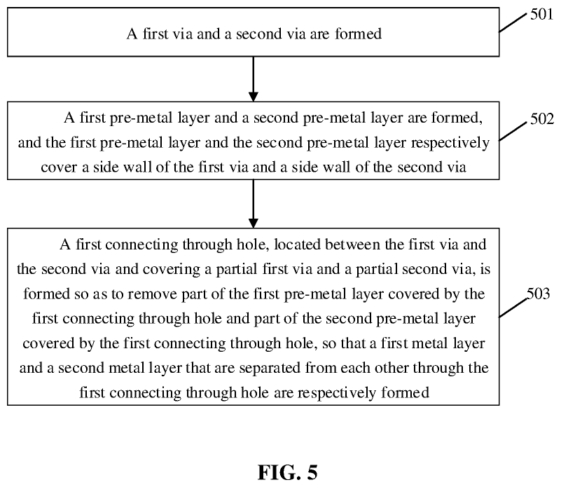

Embodiments of the disclosure further provide a method for preparing a via structure, specifically referring to FIG. 5. As shown in FIG. 5, the method includes the following operations.

At S501, a first via and a second via are formed.

At S502, a first pre-metal layer and a second pre-metal layer are formed. The first pre-metal layer covers a sidewall of the first via, and the second pre-metal layer respectively covers a sidewall of the second via.

At S503, a first connecting through hole, located between the first via and the second via and covering part of the first via and part of the second via, is formed so as to remove part of the first pre-metal layer covered by the first connecting through hole and part of the second pre-metal layer covered by the first connecting through hole, so that a first metal layer and a second metal layer are respectively formed. The first metal layer is separated from the second metal layer through the first connecting through hole.

The preparation method for the via structure provided by the embodiments of the disclosure is described in details below in combination with the specific embodiments.

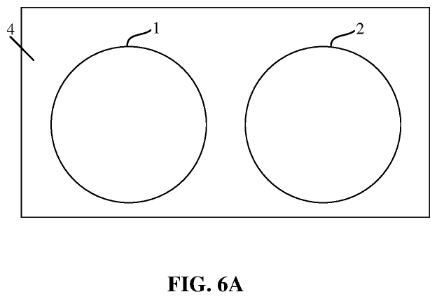

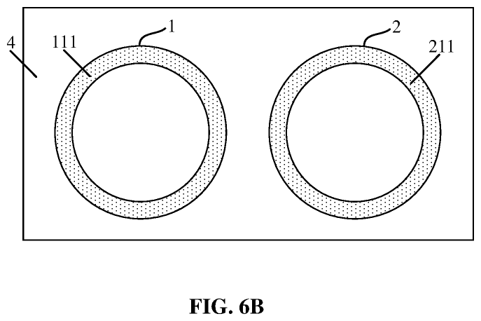

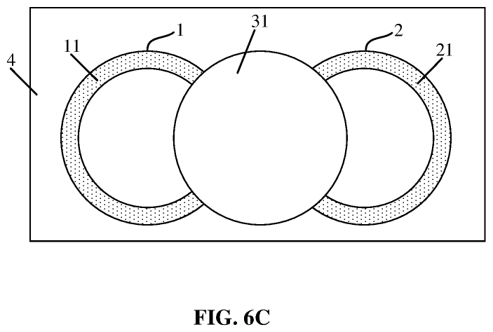

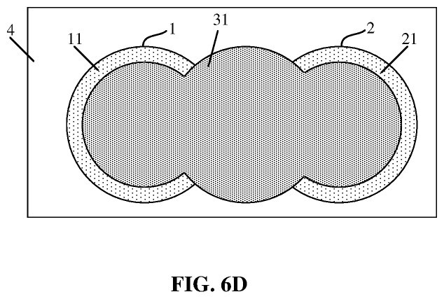

FIG. 6A to FIG. 6D are structure diagrams illustrating a via structure according to embodiments of the disclosure during the preparation.

Firstly, referring to FIG. 6A, a substrate 4 is formed before executing S501.

And then, S501 is executed, and a first via 1 and a second via 2 are formed. The first via 1 and the second via 2 are arranged on the substrate 4. Specifically, the first via 1 and the second via 2 that penetrate through the substrate 4 are formed.

Next, referring to FIG. 6B, S502 is executed, a first pre-metal layer 111 and a second pre-metal layer 211 are formed are formed in the first via 1 and the second via 2. The first pre-metal layer 111 covers a sidewall of the first via 1, and the second pre-metal layer 211 covers a sidewall of the second via 2.

Specifically, the sidewall of the first via 1 and the sidewall of the second via 2 may be electroplated, to form the first pre-metal layer 111 and the second pre-metal layer 211. The first pre-metal layer 111 and the second pre-metal layer 211 may be copper layers.

Next, referring to FIG. 6C, S503 is executed, a first connecting through hole 31, located between the first via 1 and the second via 2 and covering part of the first via 1 and part of the second via 2, is formed so as to remove part of the first pre-metal layer 111 covered by the first connecting through 31 and part of the second pre-metal layer 211 covered by the first connecting through 31, so that the first pre-metal layer 111 is disconnected with the second pre-metal layer 211, and the first metal layer 11 and the second metal layer 21 are formed. The first metal layer 11 is separated from the second metal layer 21 through the first connecting through hole 31.

The first connecting through hole 31 is arranged on the substrate 4. Specifically, the first connecting through hole 31 that penetrates through the substrate 4 is formed.

Next, referring to FIG. 6D, the method further includes: after the first connecting through hole 31 is formed, a dielectric material is filled in the first via 1, the second via 2 and the first connecting through hole 31, such that the first metal layer 11, the dielectric material and the second metal layer 21 form a capacitor. Specifically, after the dielectric material is filled, the first via is fused with the second via, so a distance between a signal of the first via and a signal of the second via can be controlled to a certain extent. The first metal layer, the dielectric material and the second metal layer can form a capacitor similar to a plane-parallel capacitor, and the impedance design and control are performed according to the distance between the two signals and a dielectric constant of the dielectric material.

In an embodiment, the radius of the first via 1 is equal to that of the second via 2. The thickness of the first metal layer 11 is equal to that of the second metal layer 21. It can be understood that when the radius of the first via is set to be equal to that of the second via, and the thickness of the first metal layer is set to be equal to that of the second metal layer, it allows that the first via and the second via, as well as the first metal layer and the second metal layer can be prepared in a same process step by using a same set of device, thus, the process operation can be simplified, and the process cost can be reduced.

It is to be noted that the radius of the first via may be unequal to that of the second via, and the thickness of the first metal layer may also be unequal to that of the second metal layer, in order to apply to different applications.

In an embodiment, the first via and the second via are partially overlapped.

As shown in FIG. 2A, a certain distance is spaced between the first via 1 and the second via 2. Specifically, the distance from the first via 1 to the second via 2 is a first distance D1 as shown in FIG. 2A. In the embodiment as shown in FIG. 2A, the first distance D1 is a shortest distance from the first via to the second via along a direction of a connecting line between a center of the first via and a center of the second via. In this embodiment, the first distance D1 is a positive number.

As shown in FIG. 2B, the first via 1 and the second via 2 are partially overlapped. Specifically, the distance from the first via 1 to the second via 2 is a first distance D1 as shown in FIG. 2B. In the embodiment as shown in FIG. 2B, the first distance D1 is a longest distance from the first via to the second via in an overlapping part of the first via and the second via along a direction of a connecting line between a center of the first via and a center of the second via. In this embodiment, the first distance D1 is a negative value of the longest distance.

In some other embodiments, the first via may be tangent to the second via (not shown in the drawings). In this embodiment, the distance from the first via to the second via is 0.

In the embodiment as shown in FIG. 2B and FIG. 3A, D3<2*R1. R1 represents the radius of the first connecting through hole 31, and D3 represents a longest distance of an overlapping part of the first via 1 and the second via 2 along a direction perpendicular to a connecting line between a center of the first via and a center of the second via. By doing so, a first pre-metal layer 111 of the first via 1 and a second pre-metal layer 211 of the second via 2 are disconnected through the first connecting through hole 31, and the first metal layer and the second metal layer that are separated through the first connecting through hole are formed, to prevent a short circuit resulted by the connection of the first metal layer with the second metal layer.

In an embodiment, a center of the first connecting through hole 31 is a midpoint of the connecting line between the center of the first via 1 and the center of the second via 2. The first connecting through hole 31 covers the first via 1 and the second via 2 with same area, such that the area of the first metal layer 11 is equal to that of the second metal layer 21. It can be understood that and in a case that the radius of the first via 1 is equal to that of the second via 2, and the thickness of the first metal layer 11 is equal to that of the second metal layer 21, the formed first metal layer and the second metal layer have the same area when area of the first via covered by the first connecting through hole equals to area of the second via covered by the first connecting through hole, namely, the first pre-metal layer and the second pre-metal layer are removed with same area. Thus, the impedance of the via structure can be well controlled and adjusted; meanwhile, the signal quality is also improved.

FIG. 3B is a structure diagram illustrating a via structure according to another embodiment of the disclosure. As shown in FIG. 3B, the quantity of the first connecting through hole may be multiple, and the adjacent first connecting through holes are mutually overlapped. of the multiple first connecting through holes may have the equal or unequal radius.

It is to be noted that person skilled in the art should aware that, in the embodiments of the disclosure, the first connecting through hole setting in a circular shape only intends to further illustrate the application of the disclosure, and is not intended to limit the disclosure in any forms. The first connecting through hole may also be any other shapes, for example, a rectangle, a pentagon and any other polygon.

In an embodiment, the first via 1 is a signal via, and the second via 2 is a reference via.

It is to be noted that the method for preparing the via structure provided by embodiments of the disclosure may also be applied to a differential signal, such that the differential signal can form tight coupling through the prepared via structure.

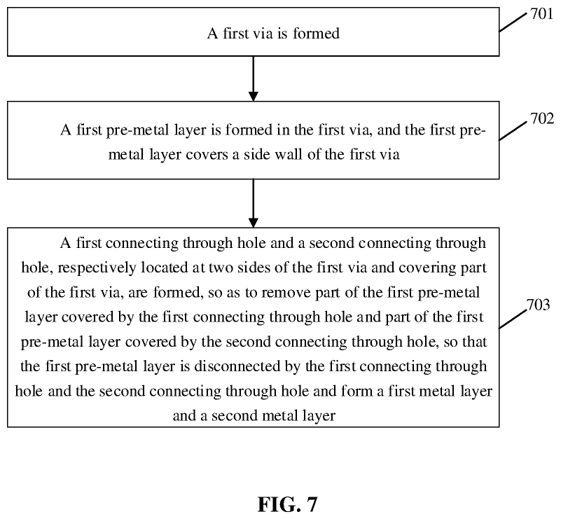

Embodiments of the disclosure further provide a method for preparing a via structure, specifically referring to FIG. 7. As shown in the figure, the method includes the following operations.

At S701, a first via is formed.

At S702, a first pre-metal layer is formed in the first via. The first pre-metal layer covers a sidewall of the first via.

At S703, a first connecting through hole and a second connecting through hole are formed so as to remove part of the first pre-metal layer covered by the first connecting through hole and the second connecting through hole, so that the first pre-metal layer is disconnected by the first connecting through hole and the second connecting through hole and a first metal layer and a second metal layer are formed. The first connecting through hole and the second connecting through hole are respectively located at two sides of the first via, and cover part of first via.

The method for preparing the via structure provided by the embodiments of the disclosure is described in details below in combination with the specific embodiments.

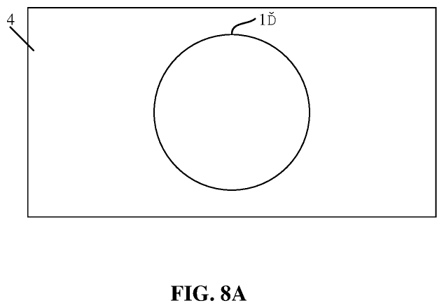

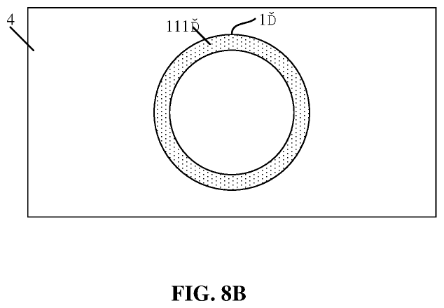

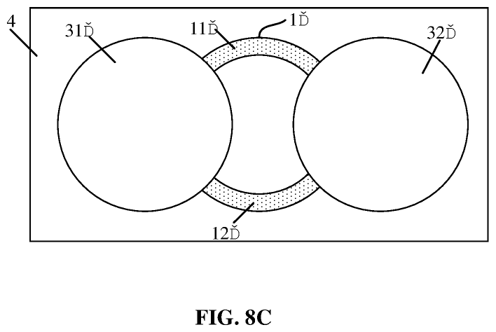

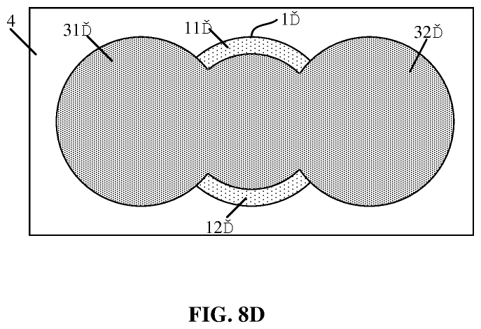

FIG. 8A to FIG. 8D are structure diagrams illustrating a via structure according to embodiments of the disclosure during the preparation.

Firstly, referring to FIG. 8A, a substrate 4 is formed before executing S701.

And then, S701 is executed, and a first via 1′ is formed. The first via 1′ is arranged on the substrate 4. Specifically, the first via 1′ that penetrates through the substrate 4 is formed.

Next, referring to FIG. 8B, S702 is executed, a first pre-metal layer 111′ is formed in the first via 1′. The first pre-metal layer 111′ covers a sidewall of the first via 1′.

Specifically, the first pre-metal layer 111′ may be formed by electroplating the sidewall of the first via 1′. The first pre-metal layer 111′ may be a copper layer.

Next, referring to FIG. 8C, S703 is executed, a first connecting through hole 31′ and a second connecting through hole 32′ are formed so as to remove part of the first pre-metal layer 111′ covered by the first connecting through hole 31′ and part of the first pre-metal layer 111′ covered by the second connecting through hole 32′, so that the first pre-metal layer 111′ is disconnected through the first connecting through hole 31′ and the second connecting through hole 32′, and the first metal layer 11′ and the second metal layer 12′ are formed. The first connecting through hole and the second connecting through hole are located at the two sides of the first via 1′ and cover part of first via 1′.

The first connecting through hole 31′ and the second connecting through hole 32′ are arranged on the substrate 4. Specifically, the first connecting through hole 31′ and the second connecting through hole 32′ that penetrate through the substrate 4 are formed.

Then, referring to FIG. 8D, the method further includes: after the first connecting through hole 31′ and the second connecting through hole 32′ are formed, the dielectric material is filled in the first via 1′, the first connecting through hole 31′ and the second connecting through hole 32′, so that the first metal layer 11′, the dielectric material and the second metal layer 12′ form a capacitor. Specifically, the first metal layer, the dielectric material and the second metal layer may form a capacitor similar to a plane-parallel capacitor. The impedance design and control are performed according to the distance between the first metal layer and the second metal layer and the dielectric constant of the dielectric material.

In an embodiment, a connecting line among the center of the first via 1′, the center of the first connecting through hole 31′ and the center of the second connecting through hole 32′ is a straight line, so that the area of the first metal layer 11′ is equal to that of the second metal layer 12′. Thus, the impedance of the via structure can be well controlled and adjusted Meanwhile, the signal quality is also improved.

It is to be noted that person skilled in the art should aware that, in the embodiments of the disclosure, the first connecting through hole setting in a circular shape only intends to illustrate the application of the disclosure, and is not intended to limit the disclosure in any forms. The first connecting through hole may also be any other shapes such as a rectangle, a pentagon and any other polygons.

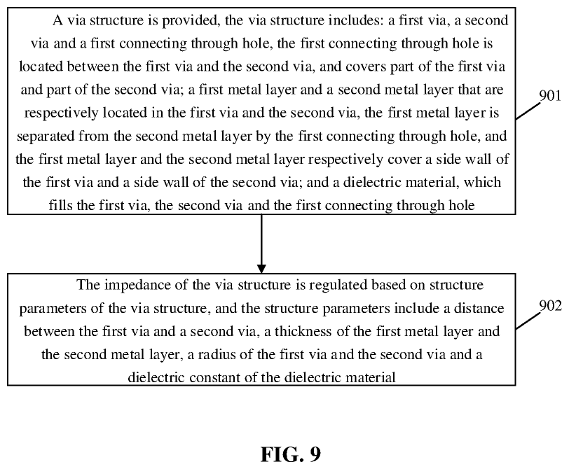

Embodiments of the disclosure further provide a method for regulating impedance of a via structure, specifically referring to FIG. 9. As shown in the figure, the method includes the following operations.

At S901, a via structure is provided. The via structure includes a first via, a second via, a first connecting through hole, a first metal layer, a second metal layer, and a dielectric material. The first connecting through hole is located between the first via and the second via, and covers part of first via and part of second via. The first metal layer is located in the first via. The second metal layer is located in the second via. The first metal layer is separated from the second metal layer by the first connecting through hole. The first metal layer covers a sidewall of the first via. The second metal layer covers a sidewall of the second via. The dielectric material fills the first via, the second via and the first connecting through hole.

At S902, the impedance of the via structure is regulated based on structure parameters of the via structure. The structure parameters include a distance between the first via and a second via, a thickness of the first metal layer and the second metal layer, a radius of the first via and the second via and a dielectric constant of the dielectric material.

The method for regulating impedance of the via structure provided by the embodiments of the disclosure is described in details below through the specific embodiments.

Firstly, as shown in FIG. 1, FIG. 3A and FIG. 3B, a via structure is provided. The via structure includes a first via 1, a second via 2, a first connecting through hole 31, a first metal layer 11, a second metal layer 21, and a dielectric material. The first connecting through hole 31 is located between the first via 1 and the second via 2, and covers part of first via 1 and part of second via 2. The first metal layer 11 is located in the first via 1. The second metal layer 21 is located in the second via 2. The first metal layer 11 is separated from the second metal layer 21 by the first connecting through hole 31. The first metal layer 11 covers a sidewall of the first via 1. The second metal layer 21 cover a sidewall of a sidewall of the second via 2. The dielectric material fills the first via 1, the second via 2 and the first connecting through hole 31.

And then, the impedance of the via structure is regulated based on structure parameters of the via structure. The structure parameters include a distance between the first via 1 and a second via 2, a thickness of the first metal layer 11 and the second metal layer 21, a radius of the first via 1 and the second via 2 and a dielectric constant of the dielectric material.

In an embodiment, the radius of the first via 1 is equal to that of the second via 2, and the thickness of the first metal layer 11 is equal to that of the second metal layer 21.

In an embodiment, the operation that the impedance of the via structure is regulated based on the structure parameters of the via structure includes the following actions.

The impedance of the via structure is regulated by using the following formulas:

$${Z}_{0} = \frac{87}{{( {ε}_{r} + 1.41 )}^{2}} * ln ( \frac{5.98 D}{0.8 * 2 R + D 2} ) \qquad ( 1 )$$

$$D = 4 R + D 1 - 2 * D 2 \qquad ( 2 )$$

Z₀ represents the impedance of the via structure, R represents the radius of the first via 1 and the second via 2, D1 represents the distance between the first via 1 and the second via 2, D2 represents the thickness of the first metal layer 11 and the second metal layer 21, εᵣ represents a dielectric constant of the dielectric material, and D represents a maximum width of the dielectric material along a direction parallel to a connecting line between the center of the first via 1 and the center of the second via 2.

It is to be noted that in the via structure as shown in FIG. 2A, D1 is a positive value, namely, the distance between the first via and the second via is positive. In the via structure as shown in FIG. 2B, D1 is a negative value, namely, the distance between the first via and the second via is negative.

In an embodiment, the impedance of the via structure may be firstly regulated through three structure parameters, namely, the radius R of the first via and the second via, the distance D1 between the first via and the second via and the thickness D2 of the first metal layer and the second metal layer. When the impedance of the via structure cannot match with that of another wiring in the PCB by regulating these three structure parameters, then the impedance of the via structure is regulated based on a dielectric parameter εᵣ of the dielectric material. Specifically, the dielectric parameter may be regulated by using different dielectric materials.

It is to be noted that there is no a related formula to clearly calculate the impedance of an annular wiring in the current technology, however, the influence factors of the via structure provided by the embodiments of the disclosure may be compared with the impedance influence factors of a microstrip line and a strip line, and compared with the impedance calculation formula of the microstrip line and the strip line, so as to obtain the impedance calculation formula for the via structure provided by the embodiments of the disclosure.

In an actual operation process, an impedance value of the via structure may be obtained through simulation or actual measurement.

The above is only optional embodiments of the disclosure and not intended to limit the protection scope of the disclosure. Any modifications, equivalent replacements, improvements and the like made within the spirit and principle of the disclosure shall fall within the protection scope of the disclosure.

1. A via structure, comprising:
a first via, a second via and a first connecting through hole, the first connecting through hole being located between the first via and the second via and covering part of the first via and part of the second via; and
a first metal layer and a second metal layer, the first metal layer being located in the first via and covering a sidewall of the first via, the second metal layer being located in the second via and covering a sidewall of the second via, wherein the first metal layer is separated from the second metal layer by the first connecting through hole.

2. The via structure of claim 1, wherein a dielectric material is filled in the first via, the second via and the first connecting through hole.

3. The via structure of claim 1, wherein a radius of the first via is equal to a radius of the second via, and a thickness of the first metal layer is equal to a thickness of the second metal layer.

4. The via structure of claim 1, wherein the first via and the second via are partially overlapped.

5. The via structure of claim 4, wherein D3<2*R1,
wherein R1 represents a radius of the first connecting through hole, and D3 represents a longest distance of the overlapping part of the first via and the second via along a direction perpendicular to a connecting line between a center of the first via and a center of the second via.

6. The via structure of claim 1, wherein a center of the first connecting through hole is a midpoint of a connecting line between a center of the first via and a center of the second via, and the first connecting through hole covers the first via and the second via with same area, so that area of the first metal layer is equal to area of the second metal layer.

7. A via structure, comprising:
a first via, a first connecting through hole and a second connecting through hole, the first connecting through hole and the second connecting through hole being respectively located at two sides of the first via and covering part of the first via; and
a first metal layer and a second metal layer, the first metal layer and the second metal layer being located in the first via, the first metal layer and the second metal layer covering a sidewall of the first via and being separated from each other by the first connecting through hole and the second connecting through hole.

8. The via structure of claim 7, wherein a dielectric material is filled in the first via, the first connecting through hole and the second connecting through hole.

9. A method for preparing the via structure of claim 1, comprising:
forming the first via and the second via;
forming a first pre-metal layer and a second pre-metal layer, wherein the first pre-metal layer covers the sidewall of the first via, and the second pre-metal layer covers the sidewall of the second via; and
forming the first connecting through hole, located between the first via and the second via and covering part of the first via and part of the second via, so as to remove part of the first pre-metal layer covered by the first connecting through hole and part of the second pre-metal layer covered by the first connecting through hole, so that the first metal layer and the second metal layer are respectively formed, the first metal layer and the second metal layer being separated from each other through the first connecting through hole.

10. The method of claim 9, further comprising:
after the forming a first connecting through hole, filling a dielectric material in the first via, the second via and the first connecting through hole.

11. The method of claim 9, wherein the first via and the second via are partially overlapped; and
D3<2*R1,
wherein R1 represents a radius of the first connecting through hole, and D3 represents a longest distance of the overlapping part of the first via and the second via along a direction perpendicular to a connecting line between a center of the first via and a center of the second via.

12. A method for preparing the via structure of claim 7, comprising:
forming the first via;
forming a first pre-metal layer in the first via, the first pre-metal layer covering the sidewall of the first via; and
forming the first connecting through hole and the second connecting through hole, respectively located at two sides of the first via and covering part of first via, so as to remove part of the first pre-metal layer that is covered by the first connecting through hole and the second connecting through hole, so that the first pre-metal layer is disconnected by the first connecting through hole and the second connecting through hole, and the first metal layer and the second metal layer are formed.

13. The method of claim 12, further comprising:
after the forming a first connecting through hole and a second connecting through hole, filling a dielectric material in the first via, the first connecting through hole and the second connecting through hole.

14. A method for regulating impedance of a via structure, comprising:
providing a via structure, the via structure comprising: a first via, a second via and a first connecting through hole, wherein the first connecting through hole is located between the first via and the second via and covers part of the first via and part of the second via; a first metal layer and a second metal layer, wherein that the first metal layer is located in the first via, and the second metal layer is located in the second via, and wherein the first metal layer is separated from the second metal layer by the first connecting through hole, and wherein the first metal layer covers a sidewall of the first via, and the second metal layer covers a sidewall of the second via; and a dielectric material, wherein the dielectric material fills the first via, the second via and the first connecting through hole; and
regulating the impedance of the via structure based on structure parameters of the via structure, wherein the structure parameters comprise a distance between the first via and a second via, a thickness of the first metal layer and the second metal layer, a radius of the first via and the second via, and a dielectric constant of the dielectric material.

15. The method of claim 14, wherein the regulating the impedance of the via structure based on structure parameters of the via structure comprises:
regulating the impedance of the via structure by using the following formulas:
$${Z}_{0} = \frac{87}{{( {ε}_{r} + 1.41 )}^{2}} * ln ( \frac{5.98 D}{0.8 * 2 R + D 2} )$$
$$D = 4 R + D 1 - 2 * D 2 ,$$
wherein Z₀ represents the impedance of the via structure, R represents the radius of the first via and the second via, D1 represents the distance between the first via and the second via, D2 represents the thickness of the first metal layer and the second metal layer, εᵣ represents the dielectric constant of the dielectric material, and D represents a maximum width of the dielectric material along a direction parallel to a connecting line between a center of the first via and a center of the second via.
